(19) United States
(12) Patent Application Publication
(10) Pub. No.: US 2020/0032932 A1
(43) Pub. Date: Jan. 30, 2020

(54) FLEXIBLE LEVEL SENSING DEVICE HAVING JUNCTION ASSEMBLY

(71) Applicant: FINETEK Co., Ltd., New Taipei City (TW)

(72) Inventors: Chih-Wen WANG, New Taipei City (TW); Ting-Kuo WU, New Taipei City (TW); Wen-Bo ZHENG, New Taipei City (TW)

(21) Appl. No.: 16/048,173

(22) Filed: Jul. 27, 2018

(51) Int. Cl. F16L 11/18; G01F 23/00; H05K 1/18; G01N 27/12; G01K 13/02

(52) U.S. Cl. CPC F16L 11/18; G01F 23/00; H05K 2201/10151; G01N 27/121; G01K 13/02; H05K 1/189

(57) ABSTRACT

A flexible liquid level sensing device includes a sensing module having a circuit board and a plurality of sensing elements. The coupled assembly includes a plurality of joining pipes connected in series. Each joining pipe includes a sleeve portion and a rotary head. The rotary head of one joining pipe is inserted into and rotatably coupled to the sleeve portion of an adjacent joining pipe. The coupled assembly forms an accommodating space for receiving the sensing module.

### TECHNICAL FIELD

The present invention relates to a liquid level sensing device and, in particular, to a flexible liquid level sensing device.

### BACKGROUND

A conventional flexible liquid level sensing device is an elongated-sensing-rod module. The flexible liquid level sensing device includes a plastic joining pipe or a rubber joining pipe acting as an outer joining pipe receiving a sensing rod. The plastic joining pipe or the rubber joining pipe is flexible and generally has acid-and-alkaline resistant properties. An electronic sensing module is usually disposed inside the plastic joining pipe or the rubber joining pipe. The plastic joining pipe or the rubber joining pipe forms a sealed space, so that the electronic sensing module is protected from being damaged or corroded.

Furthermore, the flexible liquid level sensing device is flexible and bendable to collapse for reducing a storage space. However, the sensing module inside the plastic joining pipe or the rubber joining pipe is easily damaged due to bending, resulting in frequent repair and a short product life.

In view of this, the inventor studied various technologies and created an effective solution in the present disclosure.

### SUMMARY

It is an objective of the present invention to provide a flexible liquid level sensing device which can prevent the sensing module from being damaged due to bending and is bendable to reduce a storage space; besides, it is expected to shorten the difficulty of assembly processes especially for long sensing pipe

Accordingly, the present invention provides a flexible liquid level sensing device having a coupled assembly. The flexible liquid level sensing device comprises a sensing module, an upper pipe, a coupled assembly, and a lower pipe. The sensing module includes a circuit board and a plurality of sensing elements disposed on the circuit board. The upper pipe receives one end of the sensing module. The coupled assembly includes a plurality of joining pipes connected in series, each joining pipe includes a sleeve portion and a rotary head extended from the sleeve portion. The rotary head of one of the joining pipes of the coupled assembly is inserted in and rotatably coupled to the sleeve portion of an adjacent joining pipe. One end of the coupled assembly is connected to the upper pipe to form an accommodating space for accommodating the sensing module. The lower pipe is coupled to the other end of the sensing module, and the lower pipe is connected to the coupled assembly and seals the accommodating space.

Compared to conventional techniques, the flexible liquid level sensing device has a coupled assembly between the upper pipe and the lower pipe. The coupled assembly includes multiple joining pipes connected in series. The rotary head of one of the joining pipes is inserted in and rotatably coupled to the sleeve portion of an adjacent one of the joining pipes. Any two adjacent joining pipes can rotate within a limited rotation angle range. As a result, the coupled assembly constituted by the joining pipes connected in series can only bend and collapse within the limited rotation angle range. This prevents the sensing module from being damaged by sharp bending, thus improving practicability in use.

### BRIEF DESCRIPTION OF THE DRAWINGS

The disclosure will become more fully understood from the detailed description and the drawings given herein below for illustration only, and thus does not limit the disclosure, wherein:

FIG. 1 is a perspective view illustrating a flexible liquid level sensing device according to the present invention;

FIG. 2 is a front view illustrating the flexible liquid level sensing device;

FIG. 3 is a perspective exploded view illustrating a coupled assembly of the flexible liquid level sensing device;

FIG. 4 is an exploded cross-sectional view illustrating the coupled assembly of the flexible liquid level sensing device;

FIG. 5 is an assembled cross-sectional view illustrating the coupled assembly of the flexible liquid level sensing device;

FIG. 6 is a partial cross-sectional view illustrating the flexible liquid level sensing device;

FIG. 7 is a partial enlarged view illustrating the flexible liquid level sensing device; and

FIG. 8 is a cross-sectional view illustrating that the coupled assembly is bent.

### DETAILED DESCRIPTION

Detailed descriptions and technical contents of the present disclosure are illustrated below in conjunction with the accompanying drawings. However, it is to be understood that the descriptions and the accompanying drawings disclosed herein are merely illustrative and exemplary and not intended to limit the scope of the present disclosure.

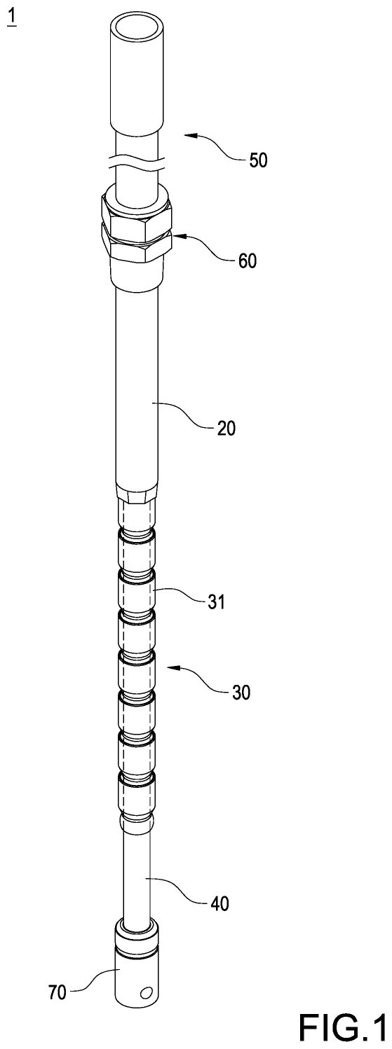

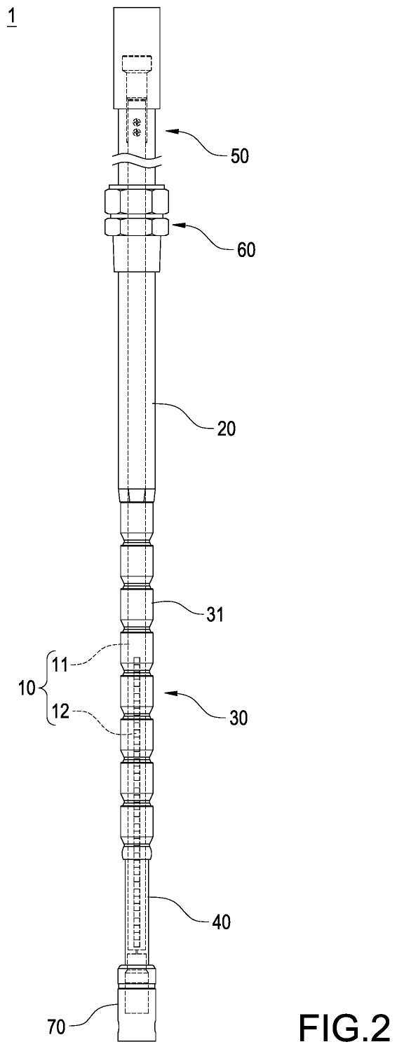

Please refer to FIGS. 1 and 2 for a perspective view and a front view illustrating a flexible liquid level sensing device according to the present invention. The flexible liquid level sensing device 1 having a coupled assembly 30 includes a sensing module 10, an upper pipe 20, a coupled assembly 30, and a lower pipe 40. The coupled assembly 30 is connected between the upper pipe 20 and the lower pipe 40 for receiving and protecting the sensing module 10. Accordingly, the sensing module 10 is protected from being damaged by contact with other object when measuring a liquid level. The flexible liquid level sensing device 1 is detailed as below.

The sensing module 10 includes a circuit board 11 and a plurality of sensing elements 12 disposed on the circuit board 11. The circuit board 11 is preferably a flexible printed circuit board.

The upper pipe 20 receives one end of the sensing module 10. In detail, the upper pipe 20 is a joining pipe consisting of a rigid material such as stainless steel or hard plastic.

The coupled assembly 30 includes a plurality of joining pipes 31 connected in series. Each joining pipe 31 includes a sleeve portion 311 and a rotary head 312 extended from the sleeve portion 311. The rotary head 312 of one of the joining pipes 31 of the coupled assembly 30 is inserted in and rotatably coupled to the sleeve portion 311 of an adjacent one of the joining pipes 31. One end of the coupled assembly 30 is connected to the upper pipe 20 to form an accommodating space 300 for accommodating the sensing module 10. Each joining pipe 31 preferably consists of hard plastic to provide rigidity.

It should be noted that, the number of the joining pipes 31 can be adjusted according to requirement, so that the flexible liquid level sensing device 1 can have a sufficient length for taking liquid level measurements.

Furthermore, the lower pipe 40 is a plastic joining pipe or rubber joining pipe and is bendable and has acid-and-alkali resistant properties. The lower pipe 40 receives the other end of the sensing module 10. The lower pipe 40 is connected to the coupled assembly 30 and seals the accommodating space 300. Accordingly, the sensing module 10 inserted in the upper pipe 20, the coupled assembly 30 and the lower pipe 40 is enclosed without contacting anything outside.

In the present embodiment, the flexible liquid level sensing device 1 includes a fixed base 50, a connection head 60 and a hanging element 70. One end of the sensing module 10 is fixed in the fixed base 50 for signal connection. Furthermore, the upper pipe 20 is connected to the fixed base 50 through the connection head 60. The hanging element 70 is coupled to an end portion of the lower pipe 40 and is used to hang a heavy object, so that the coupled assembly 30 is oriented parallel to a gravity force direction for taking liquid level measurements.

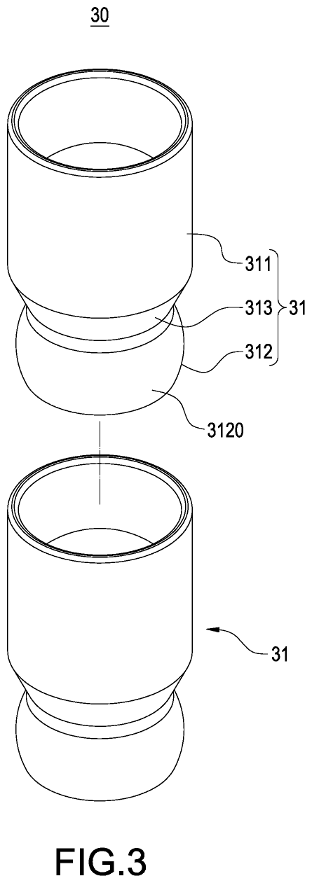

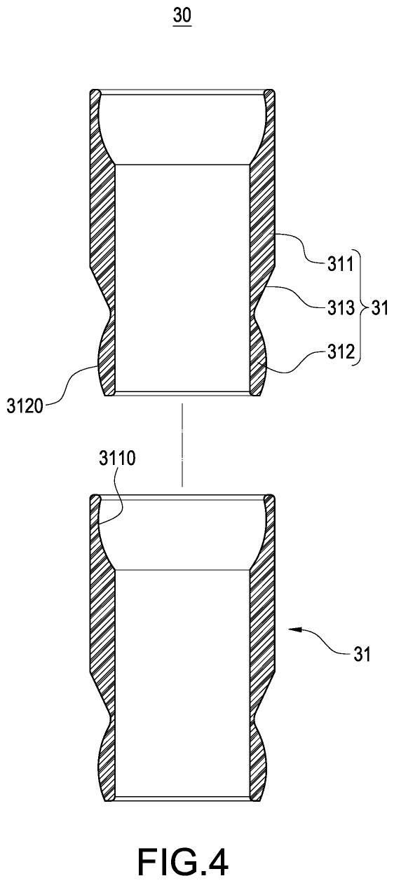

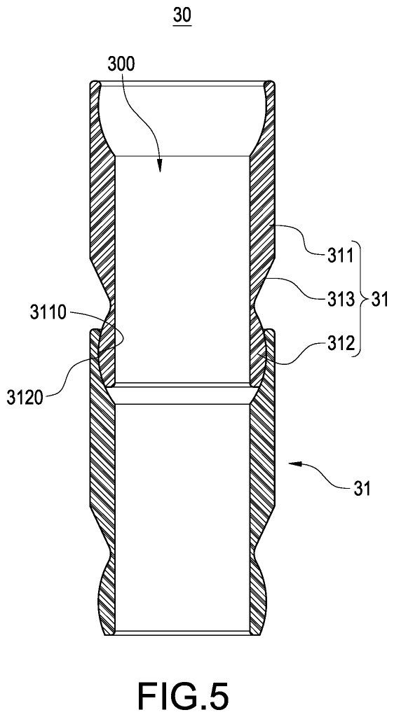

Please refer to FIGS. 3 to 5 for a perspective exploded view, an exploded cross-sectional view and an assembled cross-sectional view illustrating the coupled assembly of the flexible liquid level sensing device. In detail, an arc groove 3110 is formed on an inner surface of the sleeve portion 311. The rotary head 312 of the joining pipe 31 includes an arc surface 3120. When the joining pipes 31 are connected in series, the arc surface 3120 of the rotary head 312 of one joining pipe 31 is rotatably moved in the arc groove 3110 of an adjacent one of the joining pipes 31, so that the rotary head 312 of the joining pipe 31 is rotatably coupled to the sleeve portion 311 of the adjacent one of the joining pipes 31.

In detail, the rotary head 312 and the sleeve portion 311 of the joining pipe 31 are of one-piece form. Preferably, the joining pipe 31 includes a neck segment 313 disposed between the sleeve portion 311 and the rotary head 312. The neck segment 313 is configured to facilitate disposition of the arc surface 3120 of the rotary head 312 for achieving bending of the connected joining pipes 31.

It should be noted that, after the adjacent joining pipes 31 are connected to each other, the joining pipe 31 can rotate within a limited rotation angle range. As a result, the coupled assembly 30 constituted by the joining pipes 31 connected in series can only bend and collapse within the limited rotation angle range. This prevents the sensing module 10 from being damaged by sharp bending.

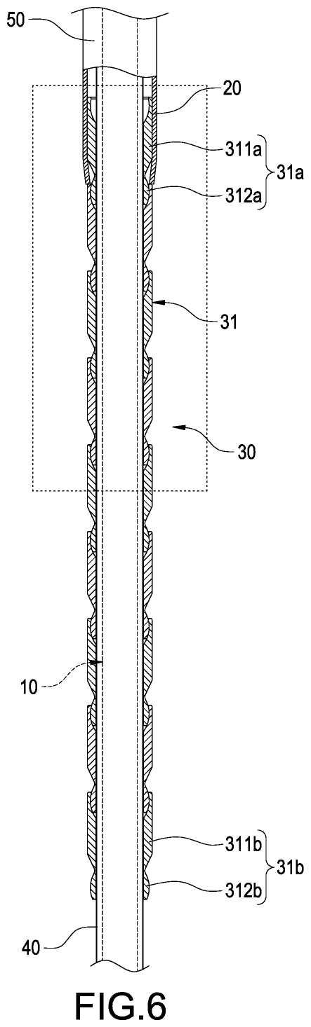

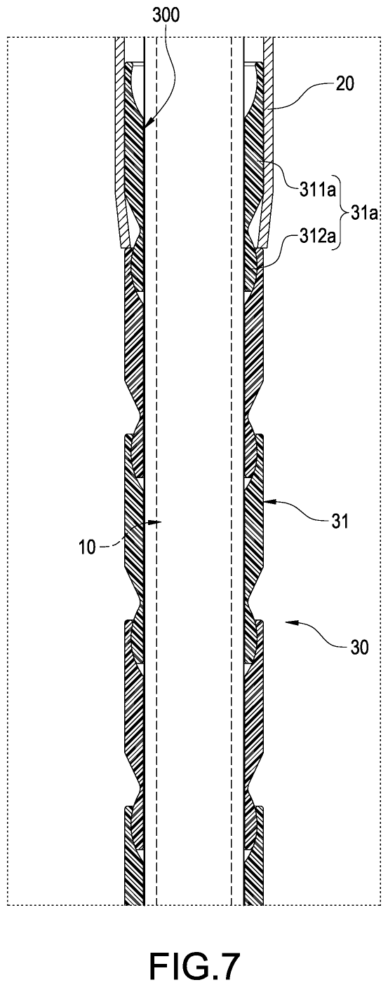

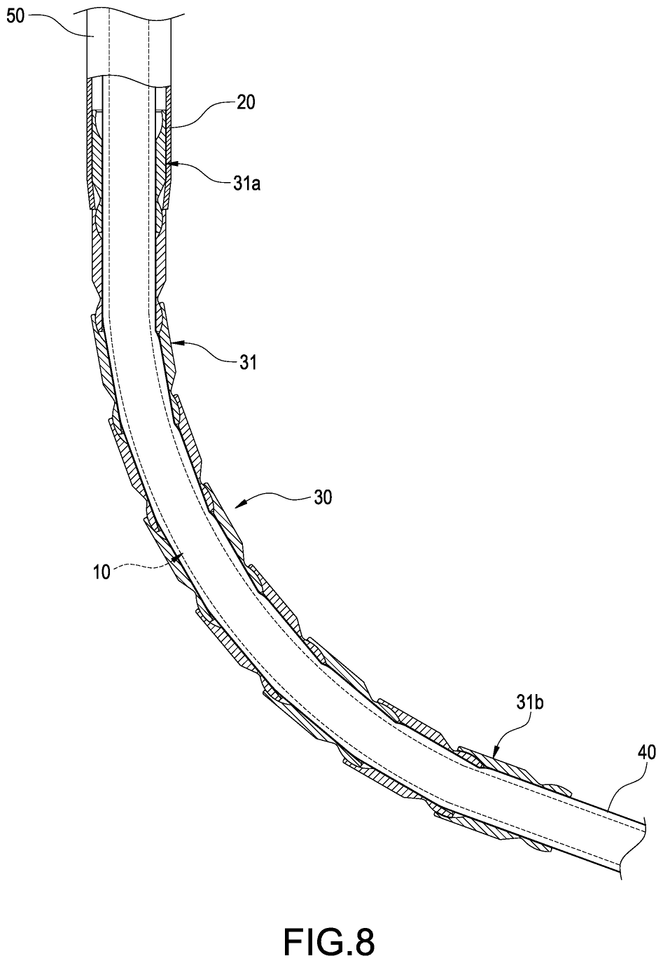

Please refer to FIGS. 6 and 7 for a partial cross-sectional view and a partial enlarged view illustrating the flexible liquid level sensing device, and please also refer to FIG. 8 for a cross-sectional view illustrating that the coupled assembly is bent. One end of the coupled assembly 30 is inserted into the upper pipe 20, and the other end of the coupled assembly 30 is inserted into the lower pipe 40.

To be specific, the coupled assembly 30 includes a first joining pipe 31a connected to the upper pipe 20, the first joining pipe 31a includes a first sleeve portion 311a and a first rotary head 312a extended from the first sleeve head 311a. The first sleeve portion 311a is inserted into the upper pipe 20.

Moreover, the coupled assembly 30 includes a second joining pipe 31b connected to the lower pipe 40. The second joining pipe 31b includes a second sleeve portion 311b and a second rotary head 312b extended from the second sleeve portion 311b. The lower pipe 40 is inserted into the second sleeve portion 311b from the second rotary head 312b.

As shown in FIG. 8, two ends of the coupled assembly 30 are inserted into the upper pipe 20 and the lower pipe 40, respectively. The coupled assembly 30 can rotate/bend within a limited angle range by means of the joining pipes 31 connected in series. Accordingly, a bending angle of the coupled assembly 30 for easy storage is limited. Furthermore, the coupled assembly 30 consists of a rigid material to provide a support force, thus preventing the coupled assembly 30 from being overly bent to cause damage to the sensing module 10.

It is to be understood that the above descriptions are merely the preferable embodiments of the present disclosure and are not intended to limit the scope of the present disclosure. Equivalent changes and modifications made in the spirit of the present disclosure are regarded as falling within the scope of the present disclosure.

What is claimed is:

1. A flexible liquid level sensing device having a coupled assembly, comprising:
a sensing module including a circuit board and a plurality of sensing elements disposed on the circuit board, where the sensing elements are temperature, level, moisture or humidity sensors;
an upper pipe receiving one end of the sensing module;
a coupled assembly including a plurality of joining pipes connected in series, each joining pipe includes a sleeve portion and a rotary head extended from the sleeve portion, the rotary head of one of the joining pipes of the coupled assembly being inserted in and rotatably coupled to the sleeve portion of an adjacent one of the joining pipes, one end of the coupled assembly being connected to the upper pipe to form an accommodating space for accommodating the sensing module; and
a lower pipe receiving the other end of the sensing module, the lower pipe being connected to the coupled assembly and sealing the accommodating space.

2. The flexible liquid level sensing device according to claim 1, further comprising a fixed base, one end of the sensing module being fixed in the fixed base.

3. The flexible liquid level sensing device according to claim 2, further comprising a connection head, the upper pipe being connected to the fixed base through the connection head.

4. The flexible liquid level sensing device according to claim 1, wherein an arc groove is formed on an inner surface of the sleeve portion, the rotary head includes an arc surface, and the arc surface of the rotary head of one of the joining pipes is rotatably moved in the arc groove of an adjacent one of the joining pipes, so that the rotary head of the joining pipe is rotatably coupled to the sleeve portion of the adjacent joining pipe.

5. The flexible liquid level sensing device according to claim 1, wherein the joining pipe further includes a neck segment disposed between the sleeve portion and the rotary head.

6. The flexible liquid level sensing device according to claim 1, wherein the coupled assembly includes a first joining pipe connected to the upper pipe, the first joining pipe includes a first sleeve portion and a first rotary head extended from the first sleeve portion, and the first sleeve portion is inserted into the upper pipe.

7. The flexible liquid level sensing device according to claim 1, wherein the coupled assembly includes a second joining pipe connected to the lower pipe, the second joining pipe includes a second sleeve portion and a second rotary head extended from the second sleeve portion, and the lower pipe is inserted into the second sleeve portion from the second rotary head.

8. The flexible liquid level sensing device according to claim 1, further comprising a hanging element, the hanging element being coupled to an end portion of the lower pipe.

9. The flexible liquid level sensing device according to claim 1, wherein each of the joining pipes consists of hard plastic.

10. The flexible liquid level sensing device according to claim 1, wherein each of the joining pipes is of one-piece form.
